(19) United States
(12) Patent Application Publication
(10) Pub. No.: US 2015/0228714 A1
(43) Pub. Date: Aug. 13, 2015

(54) ISOLATION METHODS FOR LEAKAGE, LOSS AND NON-LINEARITY MITIGATION IN RADIO-FREQUENCY INTEGRATED CIRCUITS ON HIGH-RESISTIVITY SILICON-ON-INSULATOR SUBSTRATES

(71) Applicant: RFAXIS, INC., Irvine, CA (US)

(72) Inventors: OLEKSANDR GORBACHOV, IRVINE, CA (US); EDWARD HYON SU HAN, ALISO VIEJO, CA (US)

(21) Appl. No.: 14/620,604

(22) Filed: Feb. 12, 2015

Related U.S. Application Data
(60) Provisional application No. 61/939,547, filed on Feb. 13, 2014.

(51) Int. Cl. H01L 29/06; H01L 23/58; H01L 27/12; H01L 29/78

(52) U.S. Cl. CPC H01L 29/0611; H01L 29/7838; H01L 29/0649; H01L 23/585; H01L 27/1203

(57) ABSTRACT

A radio frequency integrated circuit with a silicon-on-insulator substrate includes a buried oxide layer that is disposed over a silicon substrate. The silicon-on-insulator substrate has a silicon layer that is disposed over the buried oxide layer. The integrated circuit includes a transistor disposed on the silicon layer, and a guard-ring in the silicon-on-insulator substrate that surrounds the transistor on the silicon layer. Depletion regions on the silicon substrate corresponding to areas surrounding the transistor is defined by the application of a voltage to the guard-ring. Isolation of radio frequency transmission lines on silicon-on-insulator substrates is also possible with this configuration.

### CROSS-REFERENCE TO RELATED APPLICATIONS

This application relates to and claims the benefit of U.S. Provisional Application No. 61/939547, filed Feb. 13, 2014 and entitled “ISOLATION METHODS FOR LEAKAGE, LOSS AND NON-LINEARITY MITIGATION IN RADIO FREQUENCY INTEGRATED CIRCUITS ON HIGH-RESISTIVITY SILICON-ON-INSULATOR SUBSTRATES,” the entirety of the disclosure of which is wholly incorporated by reference herein.

### STATEMENT RE: FEDERALLY SPONSORED RESEARCH/DEVELOPMENT

Not Applicable

### BACKGROUND

1. Technical Field

The present disclosure generally relates to the field of electronics. More particularly, the present disclosure relates to radio-frequency integrated circuits (RFICs) on high-resistivity silicon-on-insulator substrates.

2. Related Art

Radio frequency (RF) is a common term for a range of frequency of electromagnetic radiation typically used to produce and detect radio waves. Such a frequency range can be in the range of 30 kilohertz (kHz) (3×10⁴ cycles/second) to 300 gigahertz (GHz) (3×10¹¹ cycles/second). Wireless communication devices may include front-end circuitry for processing or conditioning RF signals at an incoming or outgoing frequency or signal port. RF front-end circuits may be components of receiver, transmitter, or transceiver systems associated with a wireless device.

Silicon-on-insulator (SOI) semiconductor technologies are widely used for various RF applications. SOI typically refers to the use of a layered silicon-insulator-silicon substrate in place of a more conventional silicon substrate (bulk silicon substrate) in semiconductor manufacturing, especially microelectronics. In general, a SOI device consists of a semiconductor substrate on which a thin insulating layer, usually made of silicon dioxide and referred to as the “buried oxide” or “BOX,” is formed. The insulating layer may be created by flowing oxygen onto a plain silicon wafer and then heating the wafer to oxidize the silicon, thereby creating a uniform buried layer of silicon dioxide. An active region of silicon is formed on the BOX layer of the SOI substrate. The active silicon layer is intended for receiving circuit elements (e.g., transistors, thyristors, diodes) of an integrated circuit (IC).

Active elements of an integrated circuit (IC) may be separated and electrically isolated from each other by shallow trench isolation (STI) structures. STI structures are generally formed by etching a trench between the active elements and filling the trench with a low-loss dielectric material. The BOX region is intended to electrically isolate the active elements from the semiconductor substrate and effectively reduce coupling between the active elements and the underlying bulk silicon substrate.

A metal-oxide-semiconductor field-effect transistor (MOSFET) is a device that, for example, may be used to amplify or switch electronic signals. The MOSFET includes a channel of N-type or P-type semiconductor material, and is accordingly called an NMOSFET or a PMOSFET (also commonly known as NMOS, PMOS). Transistors fabricated on a SOI substrate, such SOI NMOS and SOI PMOS transistors, can form RF switches, low noise amplifiers, or power amplifiers which can be utilized in cellular phones or other electronic devices. However, capacitive coupling between source/drain regions of the transistors and the underlying bulk silicon substrate can adversely affect transistor performance, e.g., by providing an RF signal path to ground.

One approach for reducing capacitive coupling in SOI substrates utilizes a high-resistivity bulk silicon substrate, such as a bulk silicon substrate having a resistivity between several hundred Ohm-centimeter (Ohm-cm) and 10 k Ohm-cm. Some of the characteristics of a high-resistivity silicon wafer include: uniform resistivity through the thickness of the wafer; acceptable radial and axial resistivity gradients; and resistivity that remains stable throughout device processing. The use of high-resistivity silicon substrates generally increases the quality-factor (Q-factor) of passive components of RFICs (e.g., inductors, capacitors, transmission lines) and decreases overall losses. Decreased coupling between different elements of an IC may result in increased sensitivity in the receive chain and efficiency and linearity in the transmit chain of the RFIC.

However, various effects, such as trapped charge in the buried oxide layer or at the interface between the buried oxide layer and the bulk substrate can induce a surface charge on the bulk substrate. As a result, a parasitic surface conduction (PSC) layer can form on the bulk substrate, which can undesirably reduce the overall resistivity of the bulk substrate and thereby increase capacitive coupling in the SOI substrate. The PSC layer resistivity may be as low as several Ohm-cm. In general, a higher resistivity of the semiconductor substrate results in a thicker PSC layer. SOI substrates with high resistivity are prone to increased coupling between elements of the RFIC through PSC, which can undesirably increase loss, noise, and non-linear behavior.

Specialized technologies have been developed to mitigate or eliminate the risks of PSC phenomena in high-resistivity SOI substrates. These technologies are based on introducing an additional layer on top of the semiconductor substrate (called “trap-rich” layers or substrates). This layer creates additional energy states in the interface of (later-on deposited) BOX layer which keeps the surface of semiconductor substrate free or nearly free from mobile carriers and retains high resistivity of the semiconductor on its surface. Unfortunately, some of these technologies are not compatible with standard semiconductor processes (e.g., standard CMOS processes used to manufacture RFICs) and may require additional steps. Some “trap-rich” technologies are compatible with standard processes but with increased costs, which may act as a barrier to competitive pricing of the final product.

### BRIEF SUMMARY

The present disclosure is directed to active transistor isolation techniques as well as minimizing coupling on RF transmission lines and loss along with reducing non-linear effects for RF signals. The presently-disclosed devices use the “parasitic” phenomena of metal-oxide semiconductor (MOS) structures to limit parasitic surface conduction (PSC) layer in SOI high-resistivity substrates. The disclosed techniques allow use of low-cost high-resistivity SOI substrates without “trap-rich” technologies. The presently-disclosed techniques allow the use of standard low-cost silicon technologies (e.g., CMOS) for RFIC manufacturing.

According to an aspect of the present disclosure, there is a radio frequency integrated circuit. There may be a silicon-on-insulator substrate including a buried oxide layer that is disposed over a silicon substrate. The silicon-on-insulator substrate may also include a silicon layer that is disposed over the buried oxide layer. Additionally, the integrated circuit may include at least one transistor disposed on the silicon layer. Each transistor may include a gate, a drain, a source, and a body. The integrated circuit may also have a guard-ring in the silicon-on-insulator substrate that surrounds the at least one transistor on the silicon layer. Depletion regions on the silicon substrate corresponding to areas surrounding the at least one transistor may be defined by the application of a voltage to the guard-ring.

According to another embodiment, there is a radio-frequency integrated circuit that includes a semiconductor substrate, a buried oxide layer over the semiconductor substrate, and a first dielectric layer over the buried oxide layer. Additionally, the integrated circuit may also include at least one radio frequency transmission line over the first dielectric layer. There may also be at least one polysilicon line disposed on each of the opposite sides of the radio frequency transmission line in a spaced relationship. Depletion regions on the semiconductor substrate corresponding to areas overlapping the at least one polysilicon line may be defined by the application of a voltage to the at least one polysilicon line.

Yet another embodiment contemplates a radio-frequency integrated circuit that likewise includes a semiconductor substrate, a buried oxide layer over the semiconductor substrate, and a plurality of dielectric layers over the buried oxide layer. This integrated circuit may include at least one radio frequency transmission line over the plurality of dielectric layers. Moreover, there may be a plurality of isolation traces in a lateral spaced relationship to the at least one radio frequency transmission line. Each of the plurality of isolation traces may be longitudinally offset on a corresponding one of the plurality of dielectric layers. Depletion regions on the semiconductor substrate corresponding to areas overlapping the plurality of isolation traces may defined by the application of a voltage to the plurality of isolation traces.

Still another embodiment of a radio-frequency integrated circuit includes a semiconductor substrate, a buried oxide layer over the semiconductor substrate, and one or more dielectric layers. A first one of the one or more dielectric layers may be disposed over the buried oxide layer. The integrated circuit may also include a coplanar wave guide structure over the first one of the one or more dielectric layers. The coplanar wave guide structure may include a ground plane and a central conductor. Furthermore, there may be a plurality of first isolation traces in a spaced, parallel relationship to the central conductor. The first isolation traces may be disposed within lateral gaps defined by the ground plane and the central conductor. Depletion regions on the semiconductor substrate corresponding to areas overlapping with the plurality of first isolation traces may be defined by the application of a voltage to the first isolation traces.

### BRIEF DESCRIPTION OF THE DRAWINGS

Objects and features of the presently-disclosed structures for implementing radio-frequency integrated circuits (RFICs) on high-resistivity silicon-on-insulator (SOI) substrates and methods for fabrication thereof, and the presently-disclosed methods of limiting a PSC layer in a RFIC, will become apparent to those of ordinary skill in the art when descriptions of various embodiments thereof are read with reference to the accompanying drawings, of which:

FIG. 1 is a cross-sectional view of a theoretical structure including silicon-on-insulator NMOS transistors in accordance with the present disclosure;

FIG. 2 is a cross-sectional view of a structure including silicon-on-insulator NMOS transistors in accordance with another embodiment of the present disclosure;

FIG. 3 is a cross-sectional view of a structure including silicon-on-insulator NMOS transistors with equivalent parasitics related to a BOX layer and a semiconductor substrate in accordance with an embodiment of the present disclosure;

FIG. 4 is a cross-sectional view of a structure including silicon-on-insulator NMOS transistors without a MOS guard-ring in accordance with an embodiment of the present disclosure;

FIG. 5 is a layout view of silicon-on-insulator NMOS devices in accordance with an embodiment of the present disclosure;

FIG. 6 is a layout view of silicon-on-insulator NMOS devices in accordance with another embodiment of the present disclosure;

FIG. 7 is a layout view of silicon-on-insulator PMOS devices in accordance with an embodiment of the present disclosure;

FIG. 8 is a layout view of a structure including silicon-on-insulator PMOS devices in accordance with another embodiment of the present disclosure;

FIG. 9 is a cross-sectional view of a structure including a silicon-on-insulator substrate, showing the isolation principle between RF transmission lines, in accordance with an embodiment of the present disclosure;

FIG. 10 is a cross-sectional view of a structure including a silicon-on-insulator substrate, showing RF line separation, in accordance with an embodiment of the present disclosure;

FIG. 11 is a perspective view of a structure showing RF line separation in a silicon-on-insulator substrate in accordance with an embodiment of the present disclosure;

FIG. 12 is a cross-sectional view of a structure including a silicon-on-insulator substrate, showing co-planar wave-guide (CPW) separation, in accordance with an embodiment of the present disclosure; and

FIG. 13 is a cross-sectional view of a structure including a silicon-on-insulator substrate, showing CPW separation, in accordance with another embodiment of the present disclosure.

### DETAILED DESCRIPTION

Hereinafter, embodiments of structures for implementing radio-frequency integrated circuits (RFICs) on high-resistivity silicon-on-insulator (SOI) substrates thereof, and methods of limiting a PSC layer in a RFIC, are described with reference to the accompanying drawings. Like reference numerals may refer to similar or identical elements throughout the description of the figures. It is understood that the following disclosure provides many different embodiments, or examples, for implementing different features of the invention. Specific examples of components and arrangements are described below to simplify the present disclosure. Many of the processes are known to one of skill in the art and are described in general detail only.

As it is used herein, the term ohms-cm (“ohms centimeter”) generally refers to the measurement of the volume resistivity (also known as bulk resistivity) of a semiconductor material. As used herein, “SOI transistors” generally refers to transistors fabricated on a SOI substrate, and can be, for example, an NMOS or a PMOS transistor. As used herein, “electrically conductive” or simply “conductive” generally refers to the ability of a material to carry or conduct an electrical current.

This description may use the phrases “in an embodiment,” “in embodiments,” “in some embodiments,” or “in other embodiments,” which may each refer to one or more of the same or different embodiments in accordance with the present disclosure.

Various embodiments of the present disclosure provide structures for implementing RFICs on high-resistivity SOI substrates. Embodiments of the presently-disclosed devices use the “parasitic” phenomena of metal-oxide semiconductor (MOS) structures to limit parasitic surface conduction (PSC) layer in high-resistivity SOI substrates. Embodiments of the presently-disclosed devices use a MOS guard-ring to minimize RF coupling of SOI transistors through the bulk substrate by electrically isolating a conductive surface layer in the bulk silicon substrate underlying the SOI transistor.

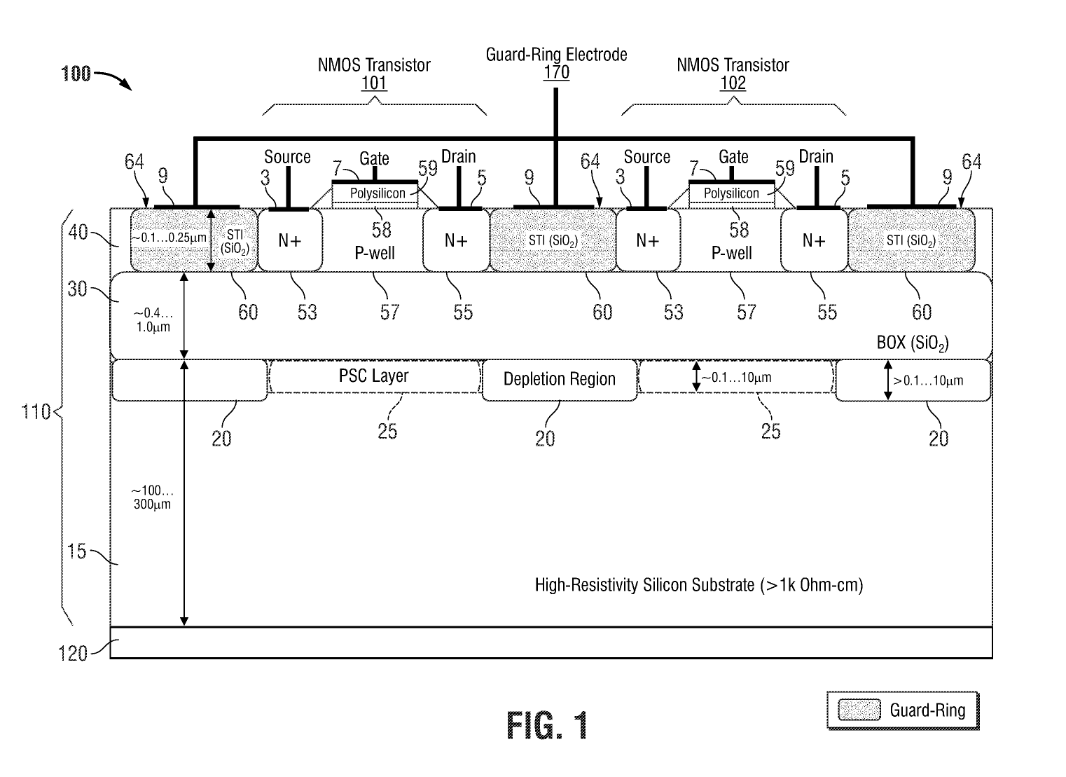

FIG. 1 illustrates a structure 100 including two SOI transistors in accordance with an embodiment of the present disclosure. The structure 100 includes a SOI substrate 110. The SOI substrate 110 includes a silicon substrate 15, such as a high-resistivity silicon (HR-Si) substrate 15, a buried oxide (BOX) layer 30, and an active layer or silicon layer 40.

The silicon substrate 15 may be either N-type or P-type, and may have any suitable thickness. In some embodiments, the silicon substrate 15 has a thickness of approximately 100 μm to 300 μm. The silicon substrate 15 may have a resistivity value of greater than 1 kOhm-cm.

In some embodiments, a conductive layer 120 (e.g., conductive ground plane) is applied at the backside of the silicon substrate 15. The conductive layer 120 may be made of metal, and may be connected to the silicon substrate 15 using an electrically-conductive adhesive material, e.g., electrically-conductive epoxy adhesive. In other embodiments, a flip-chip configuration may be used, in which case an appropriate voltage may be applied to the bulk silicon substrate 15 via a seal-ring of the integrated circuit or via additional contacts through the BOX layer 30.

The silicon layer 40 may have any suitable thickness. In some embodiments, the silicon layer 40 has a thickness range of approximately 0.1 μm to approximately 0.25 μm. The BOX layer 30 may be formed of any suitable dielectric material, using any suitable process or technique. An illustrative but non-limiting example of a suitable dielectric material is silicon dioxide (SiO₂). The BOX layer 30 may have any suitable thickness. In some embodiments, the BOX layer 30 has a thickness range of approximately 0.4 μm to approximately 1.0 μm. The BOX layer 30 may be formed by oxygen ion implantation.

As shown in FIG. 1, the first and second N-channel metal-oxide semiconductor (NMOS) transistors 101, 102 are situated above the BOX layer 30. Although two NMOS transistors are shown in FIG. 1, it is to be understood that the structure 100 may include additional, fewer, and/or different circuit elements.

Each of the first and second NMOS transistors 101, 102 includes an N-type source region 53 and an N-type drain region 55, which are arranged on opposite sides of a P-type well region 57 (also referred to herein as “gate region 57”). Source region 53, drain region 55 and the gate region are formed in the silicon layer 40, which overlies the BOX layer 30. Source region 53 and drain region 55 may be formed by doping segments of the silicon layer 40 with a suitable N-type dopant, and P-type well 57 may be formed by doping with a suitable P-type dopant. These doping schemes will be reversed in a PMOS device, and one who is skilled in the art would understand how to dope the respective structures. Source and drain electrodes 3, 5 composed of an electrically-conductive material, e.g., metal, are deposited on the source and drain regions 53, 55.

In an embodiment, a gate oxide layer 58 is situated on the gate region 57, a polysilicon layer 59 is situated on the gate oxide layer 58, and a gate electrode 7 is situated on the polysilicon layer 59. In some embodiments, sidewall spacers may be concurrently formed upon the opposed sidewall surfaces of respective gate conductors. The sidewall spacers may be composed of a dielectric material, e.g., silicon dioxide.

Also shown in FIG. 1, an isolation region 60 is disposed over the BOX layer 30 and surrounds the first and second NMOS transistors 101, 102. The isolation region 60 may be formed of SiO₂ or other suitable dielectric material and may be a shallow trench isolation (STI) region. The isolation region 60, which electrically isolates the transistors 101, 102 from each other and from a guard-ring electrode 170 on the STI, may have any suitable thickness. In some embodiments, the isolation region 60 has a thickness range of approximately 0.1 μm to approximately 0.25 μm. The isolation region 60 may be formed in the SOI substrate 110 by forming a trench in the silicon layer 40 and filling the trench with SiO₂. In some embodiments, as shown for example in FIG. 1, the conductive traces 9 of the guard-ring electrode 170 are formed directly on the isolation region 60.

An electrical voltage can be applied to the guard-ring electrode 170 so as to control a parasitic surface conduction (PSC) layer 25 of the bulk silicon substrate 15, which underlies the guard-ring electrode 170. The electrical charge can be applied to the guard-ring electrode 170 by applying an external bias voltage to the guard-ring electrode 170. Applying the external bias voltage to the guard-ring electrode 170 creates depletion regions 20 on top of the bulk silicon substrate 15 and “cuts” or limits the PSC layer 25, thus providing an additional isolation between the first and second NMOS transistors 101,102 and the rest of the circuitry. As a result of the guard-ring electrode 170, the PSC layer 25 is limited to the portions of bulk silicon substrate 15 underlying the first and second NMOS transistors 101, 102. By limiting the PSC layer 25 to the portions of bulk silicon substrate 15 underlying the first and second NMOS transistors 101, 102, the guard-ring electrode 170 prevents an RF signal from the first and second NMOS transistors 101,102 from utilizing the PSC layer 25 to travel to a SOI transistor disposed outside the guard-ring electrode 170.

In an embodiment, the guard-ring electrode 170 may be formed of a high-resistivity conductive material, e.g., high-resistance P-type or N-type polysilicon. By utilizing a conductive material with a high resistance to form the guard-ring electrode 170, the resistance of the RF path formed by the guard-ring electrode 170 can be increased and, thus, the effect of RF coupling between the first and second NMOS transistors 101, 102 and the guard-ring electrode 170 can be minimized. DC current for the voltage source applied to the guard-ring electrode is close to zero. The remaining PSC regions 20 underlying the first and second NMOS transistors 101, 102 present small “parasitic” capacitance and resistance, which may be connected to the rest of the circuitry through high resistance of either the bulk silicon substrate 15 or the depletion regions 20. SOI PMOS transistors and diodes may be isolated in a similar way.

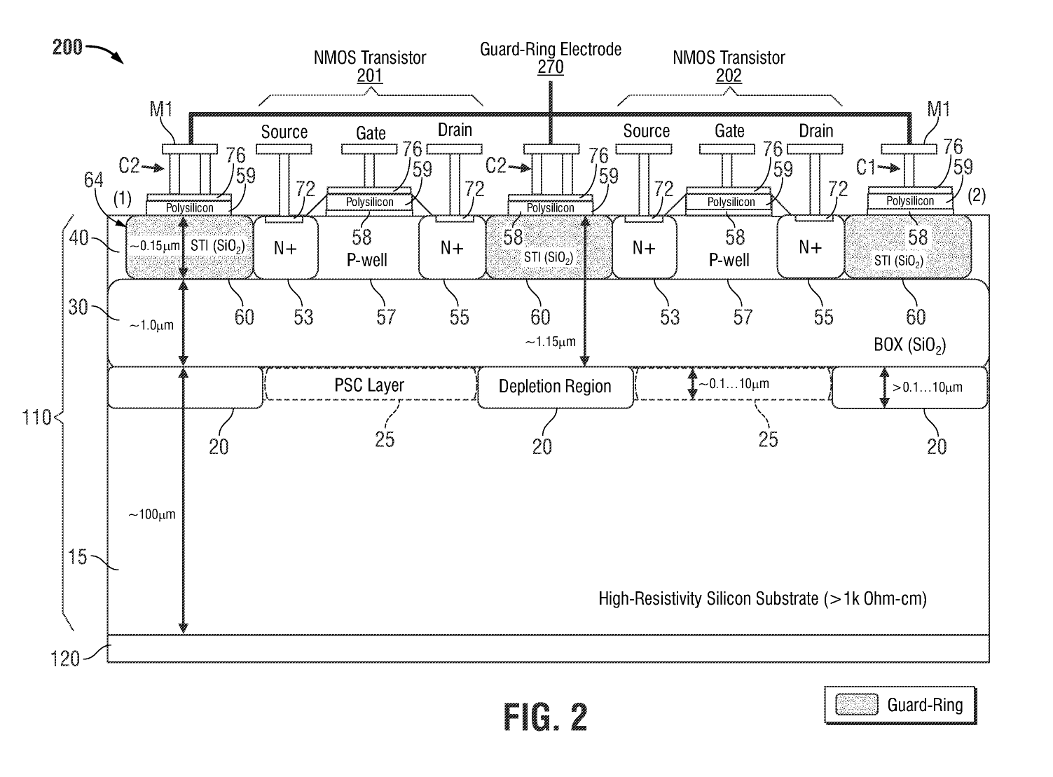

FIG. 2 shows a structure 200 including two SOI transistors in accordance with an embodiment of the present disclosure. The structure 200 is similar to the structure 100 shown in FIG. 1, except for the configuration of the guard-ring electrode 270 and the first and second NMOS transistors 201, 202.

The first and second NMOS transistors 201, 202, which are formed on the SOI substrate 110, are surrounded by an isolation region 60, e.g., similar to the first and second NMOS transistors 101, 102 shown in FIG. 1. As shown in FIG. 2, in a first configuration (1), isolation polysilicon traces 59 are situated directly on the isolation region 60, and in a second configuration (2), isolation polysilicon traces 59 are situated on an oxide layer 58 which is formed on the isolation region 60. In some embodiments, a silicide layer 76 may be formed on the polysilicon traces 59, and the electrical contacts C1, C2 of the guard-ring electrode 270 may be formed on the silicide layer 76. In other embodiments, a non-silicide layer may be formed on top of the polysilicon traces 59 of the guard-ring electrode 270. The silicide layer 72 may also be formed on the source and drain regions 53, 55. Any suitable metals and contacts having different shapes, levels and/or connections may be used instead of polysilicon, and reference thereto is by way of example only and not of limitation. Along these lines, reference to the silicide layer 76 is also by way of example only, and a non-silicide process may also be utilized. Structures of the guard-ring electrode 270 may be created at higher level dielectric layers as well. Polysilicon with N-type or P-type doping may be used. As a result of the guard-ring electrode 270, the PSC layer 25 is limited to the portions of bulk silicon substrate 15 underlying the first and second NMOS transistors 201, 202.

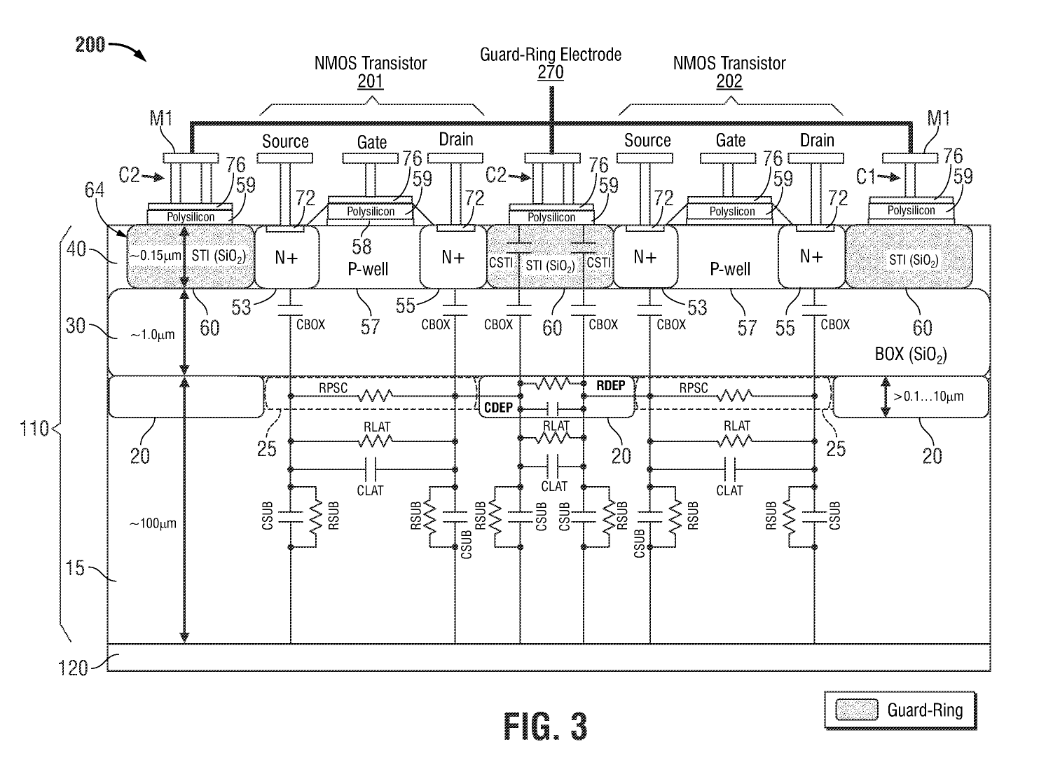

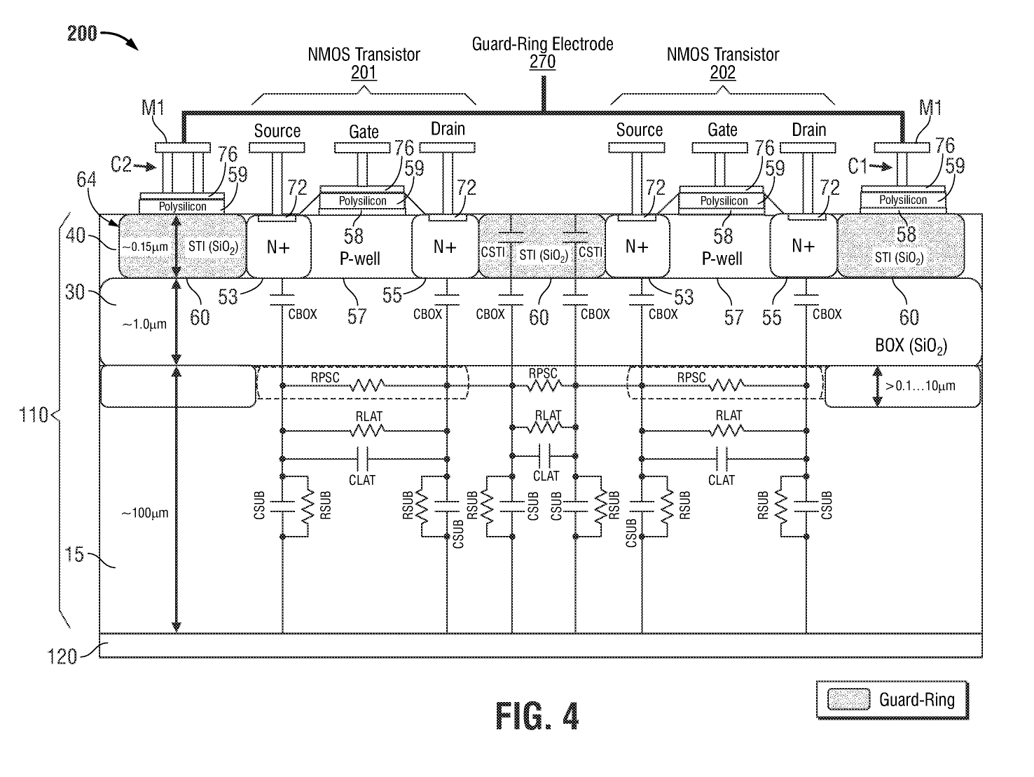

FIGS. 3 and 4 schematically illustrate equivalent resistance and capacitance in different regions of the structure 200, e.g., to identify parts of the “parasitic” paths that result in the limiting of the PSC layer 25. In FIG. 3, the resistor RDEP depicts an equivalent resistance and the capacitor CDEP depicts an equivalent capacitance of the depletion regions 20 created by the guard-ring 64 with an appropriately applied voltage level to the guard-ring electrode 270.

Referring to FIGS. 3 and 4, the resistor RPSC depicts a parasitic resistance of the PSC layer in the bulk silicon substrate 15. The capacitors CSTI depict an equivalent capacitance of the isolation region 60. The respective capacitors CBOX, which depict an equivalent capacitance of the BOX layer 60, are connected to the respective source and drain regions 53, 55 of the first and second NMOS transistors 201, 202 and the capacitors CSTI of the isolation region 60 underlying the guard-ring electrode 270. Resistor RDEP may have significantly higher value compared to RPSC with proper voltage applied to the guard-ring electrode.

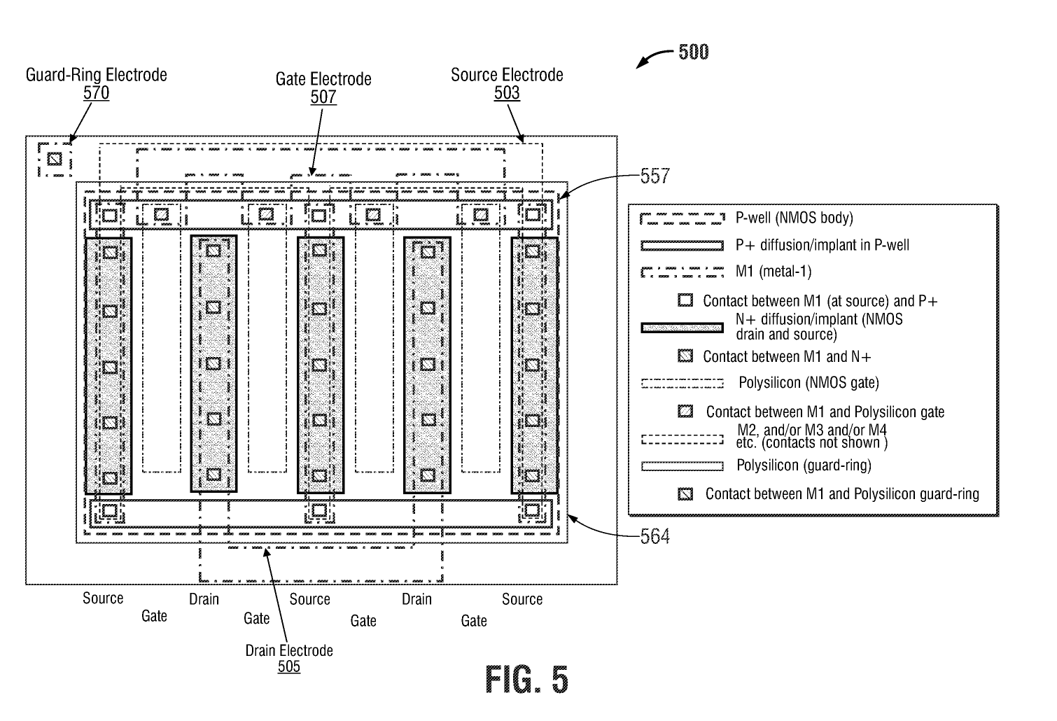

FIG. 5 is a layout view (not to scale) of silicon-on-insulator NMOS devices in accordance with an embodiment of the present disclosure. FIG. 5 schematically illustrates a four-gate NMOS transistor cell layout format (generally designated by reference numeral 500) for the case in which the body of the NMOS transistor 557 is connected to the source electrode 503. The transistor cell is surrounded by a guard-ring 564. The guard-ring 564 may be made of polysilicon. The guard-ring 564 isolates the area underlying the transistor cell from the rest of the bulk silicon substrate (situated below BOX dielectric layer) when an appropriate voltage is applied to the guard-ring electrode 570. The number of transistor cells surrounded by a common guard-ring 564 may be varied from the configuration depicted in FIG. 5. Various metals and contacts having different shapes, levels, and connections may be used. As contemplated for this embodiment as well as the other embodiments of the present disclosure, standard layout rules can be used which is defined by appropriate semiconductor process node.

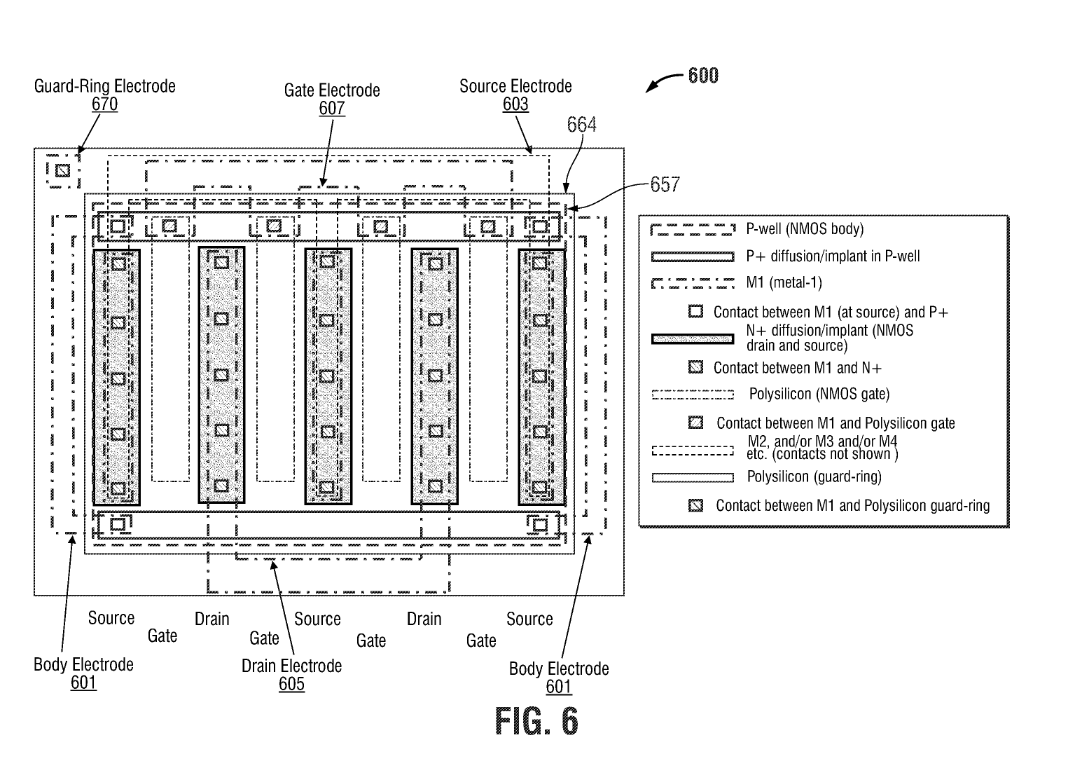

FIG. 6 is a layout view of silicon-on-insulator NMOS devices in accordance with another embodiment of the present disclosure. FIG. 6 schematically illustrates a four-gate NMOS transistor cell layout format (generally designated by reference numeral 600) for the case in which the body of the NMOS transistor 657 is independent of the source electrode 603. The transistor cell is surrounded by a guard-ring 664. The guard-ring 664 may be made of polysilicon. The guard-ring 664 isolates the area underlying the transistor cell from the rest of bulk silicon substrate (situated below the BOX dielectric layer) when an appropriate voltage is applied to the guard-ring electrode 670. The number of transistor cells surrounded by a common guard-ring 664 may be varied from the configuration depicted in FIG. 6. Various metals and contacts having different shapes, levels, and connections may be used.

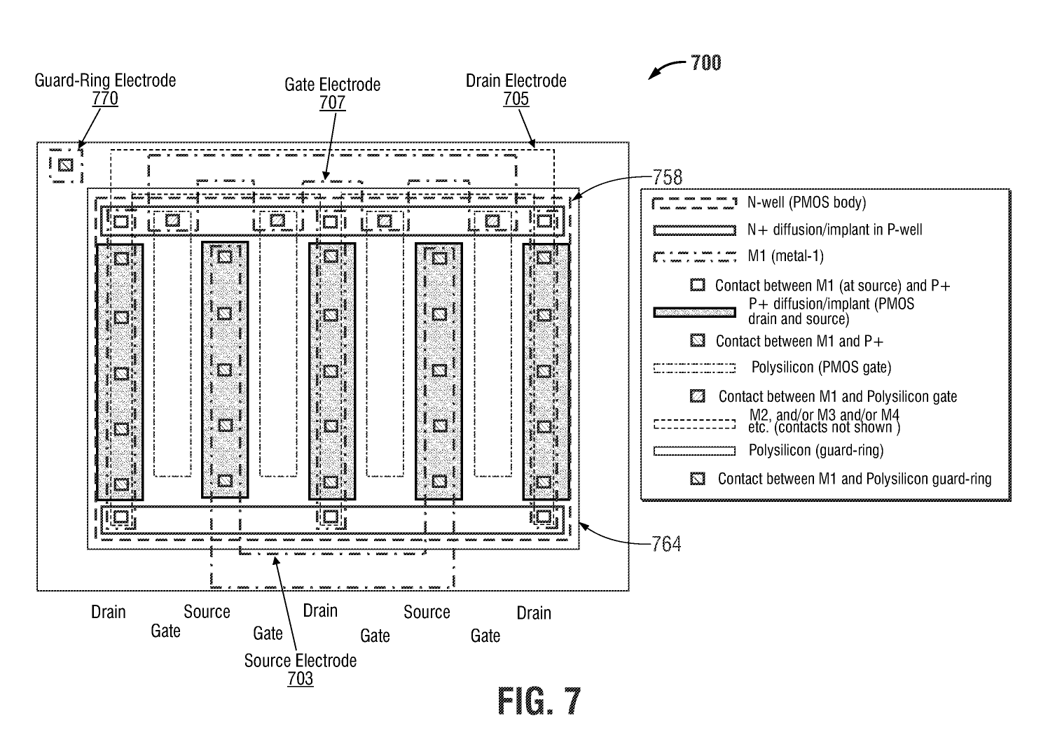

FIG. 7 is a layout view of silicon-on-insulator PMOS devices in accordance with an embodiment of the present disclosure. FIG. 7 schematically illustrates a four-gate PMOS transistor cell layout format (generally designated by reference numeral 700) for the case in which the body of the PMOS transistor 758 is connected to the drain electrode 705. The transistor cell is surrounded by a guard-ring 764. The guard-ring 764 may be made of polysilicon. The guard-ring 764 isolates the area underlying the transistor cell from the rest of bulk silicon substrate (situated below the BOX dielectric layer) when an appropriate voltage is applied to the guard-ring electrode 770. The number of transistor cells surrounded by a common guard-ring 764 may be varied from the configuration depicted in FIG. 7. Various metals and contacts having different shapes, levels, and connections may be used.

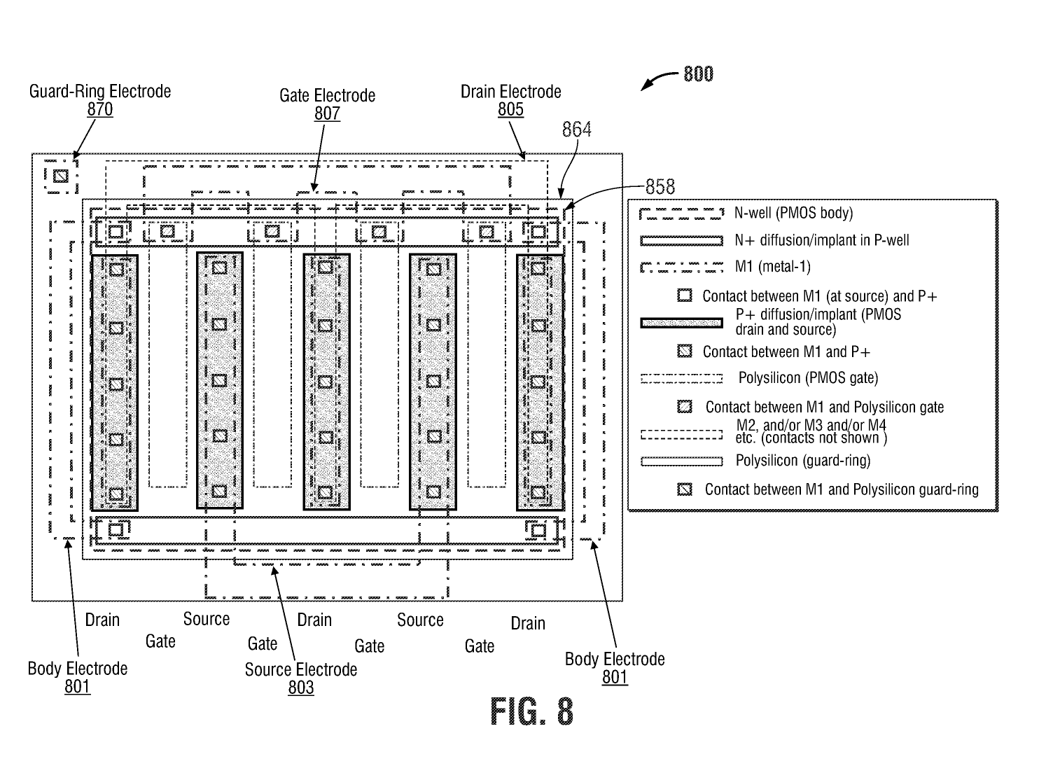

FIG. 8 is a layout view of silicon-on-insulator PMOS devices in accordance with an embodiment of the present disclosure. FIG. 8 schematically illustrates a four-gate PMOS transistor cell layout format (generally designated by reference numeral 800) in which body of the PMOS transistor 858 is independent of the of drain electrode. The transistor cell is surrounded by a guard-ring 864. The guard-ring 864 may be made of polysilicon. The guard-ring 864 isolates the area underlying the transistor cell from the rest of bulk silicon substrate (below the BOX dielectric) when a proper voltage is applied to the guard-ring electrode 870. The number of transistor cells surrounded by a common guard-ring 864 may be varied from the configuration depicted in FIG. 8. Various metals and contacts having different shapes, levels, and connections may be used.

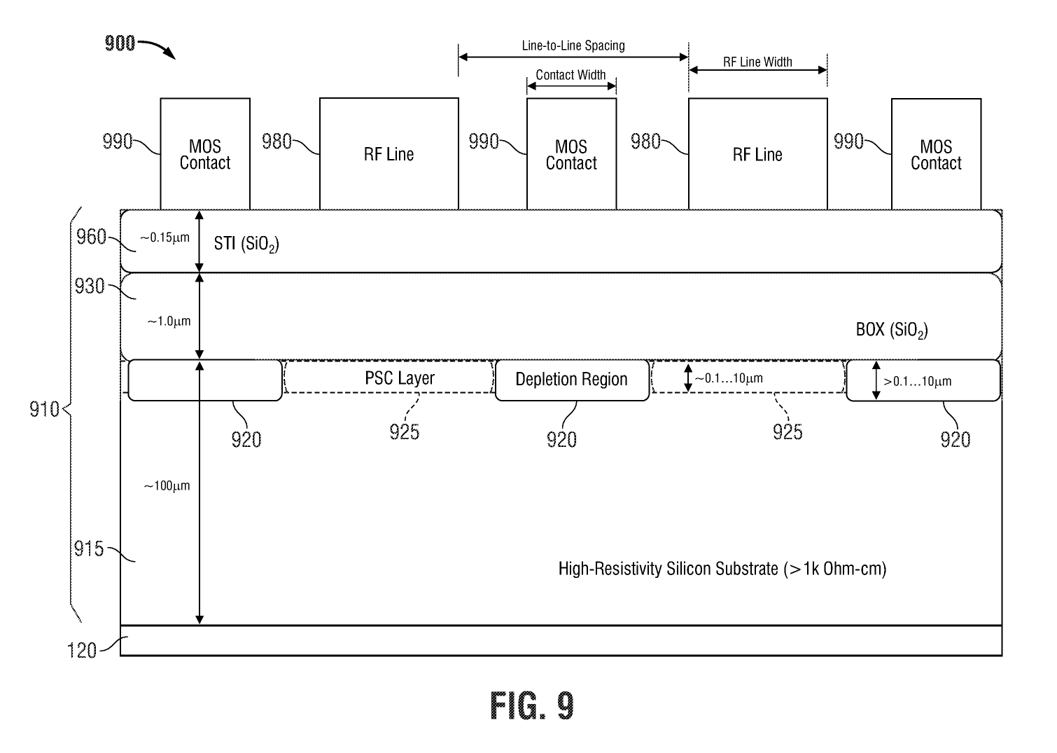

FIG. 9 is a cross-sectional view of a structure 900 that includes a SOI substrate 910 in accordance with an embodiment of the present disclosure. The SOI substrate 910 includes a buried oxide (BOX) layer 930 overlying a semiconductor substrate 915, such as a high-resistivity silicon substrate 915, and a dielectric layer 960 situated over the BOX layer 930. The semiconductor substrate 915 may be either N-type or P-type.

In some embodiments, a conductive layer 120 (e.g., conductive ground plane) is applied at the backside of the silicon substrate 915. The conductive layer 120 may be made of metal, and may be connected to the silicon substrate 915 using an electrically-conductive adhesive material, e.g., electrically-conductive epoxy adhesive. In other embodiments, a flip-chip configuration may be used, in which case an appropriate voltage may be applied to bulk silicon substrate 915 via the seal-ring of the IC or via additional contacts through the BOX layer 930.

The BOX layer 930 may be formed of any suitable dielectric material, using any suitable process or technique. An illustrative but non-limiting example of a suitable dielectric material is silicon dioxide (SiO₂). The BOX layer 930 may have any suitable thickness. In some embodiments, the BOX layer 930 has a thickness of approximately 1.0 μm.

The dielectric layer 960 may consist of any suitable dielectric material, e.g., silicon dioxide (SiO₂), and may be formed by using any suitable process, e.g., shallow trench isolation (STI). The dielectric layer 960 may have any suitable thickness. In an embodiment, the dielectric layer 960 has a thickness of approximately 0.15 μm.

The structure 900 includes RF transmission lines 980 made of conductive material formed on the dielectric layer 960. In some embodiments, the surface of the dielectric layer 960 is covered with copper foil, and the copper foil is patterned so as to obtain the RF transmission lines 980. In addition, the structure 900 includes electrodes, e.g., metal-oxide-semiconductor (MOS) contacts 990, situated between the RF transmission lines 980. Applying a DC bias to the electrodes creates depletion layers 920 in the surface of the semiconductor substrate 915, which, in turn, limits the parasitic surface conduction (PSC) layer 925. The RF line width, the line-to-line spacing, and the contact width may be varied from the configuration shown in FIG. 9.

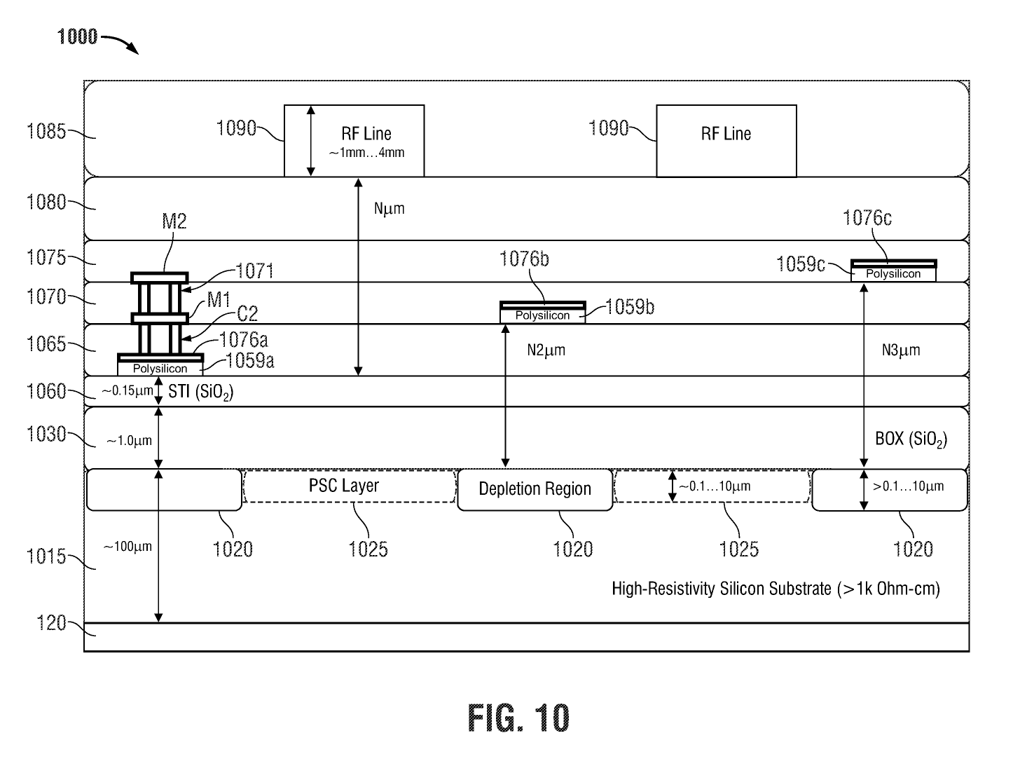

FIG. 10 is a cross-sectional view of a structure 1000 including a SOI substrate in accordance with another embodiment of the present disclosure. The structure 1000 includes a buried oxide (BOX) layer 1030 overlying a semiconductor substrate 1015, such as a high-resistivity silicon (HR-Si) substrate 1015, and a first dielectric layer 1060 situated on the BOX layer 1030. The structure 1000 includes RF transmission lines 1090 that are separated by a dielectric layer stack (layers 1065, 1070, 1075, 1080) from an active transistor region that typically corresponds to a STI layer, which is situated above the BOX layer 1030. The RF transmission lines 1090 may be separated from the first dielectric layer 1060 by a dielectric layer stack with thickness N μm. The total thickness of dielectric layer stack is in the range of several μm to above 10 μm.

In some embodiments, the silicon substrate 1015 has a thickness of approximately 100 μm. The silicon substrate 1015 may have a resistivity valve of greater than 1 kOhm-cm. In some embodiments, a conductive layer 120 (e.g., conductive ground plane) is applied at the backside of the silicon substrate 1015. The conductive layer 120 may be made of metal, and may be connected to the silicon substrate 1015 using an electrically-conductive adhesive material, e.g., electrically-conductive epoxy adhesive. In other embodiments, a flip-chip configuration may be used, in which case an appropriate voltage may be applied to the bulk silicon substrate 1015 via a seal-ring of the IC or via additional contacts through the BOX layer 1030.

The BOX layer 1030 may be formed of any suitable dielectric material, using any suitable process or technique. An illustrative but non-limiting example of a suitable dielectric material is silicon dioxide (SiO₂). The BOX layer 1030 may have any suitable thickness. In some embodiments, the BOX layer 1030 has a thickness of approximately 1.0 μm.

The first dielectric layer 1060 may consist of any suitable dielectric material, e.g., silicon dioxide (SiO₂), and may be formed by using any suitable process, e.g., shallow trench isolation (STI). The first dielectric layer 1060 may have any suitable thickness. In an embodiment, the first dielectric layer 1060 has a thickness of approximately 0.15 μm. As shown in FIG. 10, a first polysilicon trace 1059a is situated on the first dielectric layer 1060, and a first silicide layer 1076a is formed on the first polysilicon trace 1059a. A second dielectric layer 1065 is formed on the first dielectric layer 1060, and a trace M1 is formed on the second dielectric layer 1065 and electrically connected via a contact C2 to the first silicide layer 1076a. A second polysilicon trace 1059b is situated on the second dielectric layer 1065, and a second silicide layer 1076b may be formed on the second polysilicon trace 1059b. The second polysilicon isolation line 1059b may be separated from silicon substrate 1015 by a dielectric layer stack with thickness N2 μm.

In an embodiment, a third dielectric layer 1070 is formed on the second dielectric layer 1065. A third polysilicon trace 1059c may be situated on the third dielectric layer 1070, and a third silicide layer 1076c may be formed on the third polysilicon trace 1059b.

The third polysilicon trace 1059c may be separated from silicon substrate 1015 by a dielectric layer stack with thickness N3 μm. A fourth dielectric layer 1075 may be formed on the third dielectric layer 1070. In some embodiments, a fifth dielectric layer 1080 is formed on the fourth dielectric layer 1075, and RF transmission lines 1090 are formed on the fifth dielectric layer 1080. The RF transmission lines 1090 (e.g., micro-strip, coplanar, etc.) may be made from a thick metal layer to reduce metal loss. The RF transmission lines 1090 may have a thickness range of approximately 1 mm to approximately 4 mm. In some embodiments, the second dielectric layer 1065, the third dielectric layer 1070, the fourth dielectric layer 1075, and the fifth dielectric layer 1080 may have the same or similar dielectric properties. The overall thickness of the dielectric layer stack disposed between the RF transmission lines 1090 and the semiconductor substrate 1015, the DC bias applied to transmission line, the dielectric properties of the respective dielectric layers along with the different types of charges in the dielectric layers define the thickness and resistivity of the parasitic surface conduction (PSC) layer disposed underlying the RF transmission lines 1090 and in close vicinity with respect to horizontal direction (e.g., up to several micrometers). The dielectric layer 1085 is typically deposited on top of and surrounding RF line traces 1090, and may be referred to as a passivation layer. It may include more than one dielectric as well. Polysilicon strips isolating RF lines may be placed at layer. Metal trace routing providing bias voltage to an appropriate polysilicon isolation strip may be on any layer in line with generic layout rules for a particular semiconductor process node.

In accordance with various embodiments of the present disclosure, which may be fully compatible with standard CMOS and/or other silicon processes, an additional metal or polysilicon layer (e.g., isolation traces) is situated between the RF transmission lines (e.g., RF transmission lines 1090 shown in FIG. 10) along their longitudinal direction. Metal or polysilicon trace(s) may be placed either directly onto a STI layer or on top of a higher level dielectric layer. Applying an appropriate DC bias (positive, negative or zero) to the metal or polysilicon line(s), may create either flat-band or depletion or weak inversion for the metal-oxide-semiconductor (MOS) at which the semiconductor surface has very few mobile carriers with appropriately high resistivity (shown in the figures as a depletion region, for simplicity). Thus, when the RF traces are separated by high-resistivity depletion regions, coupling between lines may be minimized.

During operation, an appropriate biasing voltage is applied to the isolating metal or polysilicon traces to create a “regular” depletion area, wherein the depth of the depletion layer within the silicon substrate is higher than the “typical” accumulation area that originally creates a parasitic surface conduction (PSC) layer. Different types of metals may be used to define the original flat-band voltage (e.g., semiconductor surface resistivity has the same level as original bulk resistivity). N-type or P-type of polysilicon may be used with different doping density to also define the original flat-band voltage. If polysilicon isolation traces are used, the traces may be either silicide or non-silicide (silicide traces have lower surface resistivity compare to non-silicide traces).

If polysilicon isolation traces are used, different implants may be used on top. In such case, diffused molecules of implants into the body of polysilicon can create particular charge traps (positive or negative), which may change voltage required to create depletion region in semiconductor surface. The biasing voltage applied to the isolating metal or polysilicon traces may be implemented through contacts to different metal layers. Different cleaning processes may be used during deposition of dielectric layers. This defines the residual number of charge traps (positive or negative) within the dielectric layers, which, in turn, defines the original flat-band voltage. The silicon semiconductor substrate may be either N-type or P-type. The higher the overall dielectric thickness between the metal or polysilicon lines and the semiconductor substrate, the higher the DC voltage that may be applied (e.g., up to several Volts) to keep the depletion layer at a high-resistivity level (e.g., similar to semiconductor bulk resistivity, or higher).

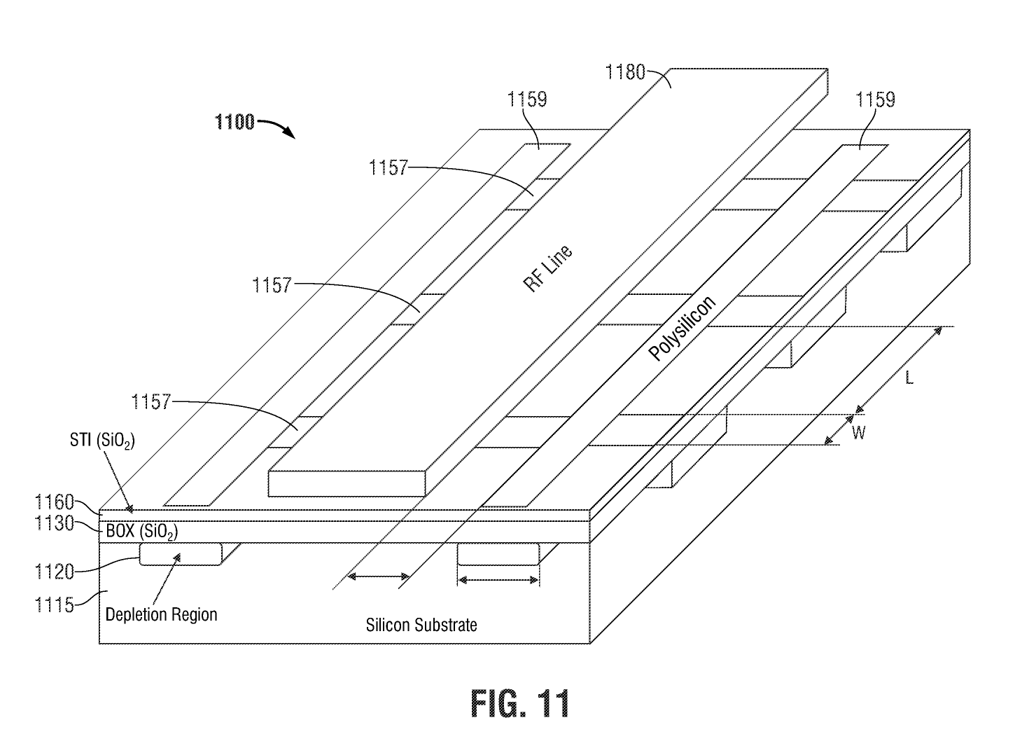

FIG. 11 is an enlarged, perspective view of a structure 1100 including a SOI substrate in accordance with an embodiment of the present disclosure. The structure 1100 includes a silicon substrate 1115, such as a high-resistivity silicon (HR-Si) substrate 1115, a buried oxide (BOX) layer 1130 overlying the silicon substrate 1115, and a dielectric layer 1160 situated on the BOX layer 1130. One or more RF transmission lines 1180 may be formed on the dielectric layer 1160.

Polysilicon lines 1159 disposed on opposite sides of the RF transmission line 1180 are situated on the dielectric layer 1160 and arranged to longitudinally extent in the direction of the longitudinal axis of the RF transmission line 1180. As shown in FIG. 11, the RF transmission line 1180 and the polysilicon lines 1159 are situated overlying a plurality of polysilicon lines 1157, which are arranged in parallel in an orthogonal direction with respect to the polysilicon lines 1159. The polysilicon lines 1157 underlying the RF transmission line 1180 are electrically connected together with the polysilicon lines 1159 which are biased by the same DC bias to create a flat-band, depletion or weak inversion layer in the semiconductor substrate surface 1115 with high resistivity. The polysilicon lines 1157 have width W, and the spacing L between the polysilicon lines 1157 may be at least several times (e.g., 10 times) lower than the RF signal wavelength, which results in decreased eddy current in the remaining PSC “patches” on the silicon substrate 1115 surface and reduces overall loss. These “patches” are electrically connected through high resistances to each other and to the silicon substrate 1115.

In some embodiments, the polysilicon lines 1159, 1157 are used without silicide, which may reduce the overall influence on RF signal propagation through these lines (lower insertion loss, lower harmonics, lower coupling, etc.). The size, shape and relative spacing of the polysilicon lines and interconnections may differ from the configuration shown in FIG. 11.

In some embodiments, different materials may be sputtered onto the polysilicon, e.g., to allow the introduction of additional charges which compensate for charges within the BOX layer 1130 and other dielectric layers underlying the MOS. Various silicon processes may be used for placement of polysilicon layers on top of different dielectric layers in the complete IC. RF transmission lines 1180 having different widths may be used, and the thickness and type of material may be chosen to minimize RF signal disturbance.

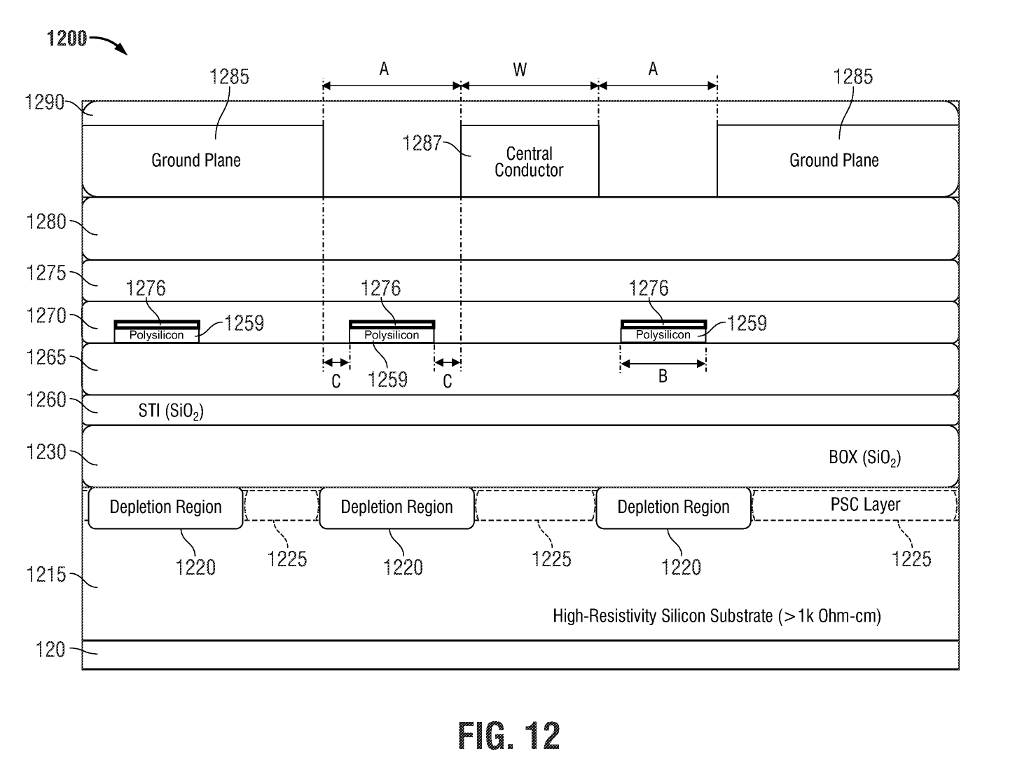

FIG. 12 is a cross-sectional view of a structure 1200 including a SOI substrate, showing co-planar wave-guide (CPW) separation, in accordance with an embodiment of the present disclosure. The CPW structure is composed of a central conductor line 1287 and ground planes 1285, where the impedance of the central conductor line 1287 depends on the width W of the central conductor line 1287 and the spacing A between the central conductor line 1287 and the ground planes 1285.

The structure 1200 includes a buried oxide (BOX) layer 1230 overlying a semiconductor substrate 1215, such as a high-resistivity silicon (HR-Si) substrate 1215, and a first dielectric layer 1260 situated on the BOX layer 1230. The substrate 1215 may have any suitable thickness. The silicon substrate 1215 may have a resistivity value of greater than 1 kOhm-cm.

In some embodiments, a conductive layer 120 (e.g., conductive ground plane) is applied at the backside of the silicon substrate 1215. The conductive layer 120 may be made of metal, and may be connected to the silicon substrate 1215 using an electrically-conductive adhesive material, e.g., electrically-conductive epoxy adhesive. In other embodiments, a flip-chip configuration may be used, in which case an appropriate voltage (e.g., 0V) may be applied to the bulk silicon substrate 1215 via a seal-ring of the IC or via additional contacts through the BOX layer 1230.

The BOX layer 1230 may be formed of any suitable dielectric material, e.g., silicon dioxide (SiO₂), using any suitable process or technique. The BOX layer 1230 may have any suitable thickness. The first dielectric layer 1260 may consist of any suitable dielectric material, e.g., silicon dioxide (SiO₂), and may be formed by using any suitable process, e.g., shallow trench isolation (STI). The first dielectric layer 1260 may have any suitable thickness.

As shown in FIG. 12, a second dielectric layer 1265 is formed on the first dielectric layer 1260, and polysilicon traces 1259 are situated on the second dielectric layer 1265. A silicide layer 1276 is situated on each of the polysilicon traces 1259. In some embodiments, a third dielectric layer 1270 is formed on the second dielectric layer 1265, a fourth dielectric layer 1275 is formed on the third dielectric layer 1270, and a fifth dielectric layer 1280 is formed on the fourth dielectric layer 1275. A central conductor 1287 and ground planes 1285 are formed on top of the dielectric layer stack, e.g., on the fifth dielectric layer 1280.

In an embodiment, a sixth dielectric layer 1290 is formed on the fifth dielectric layer 1280 and covers the CPW. Although the polysilicon isolation lines 1259 are shown on the second dielectric layer 1265, one or more polysilicon isolation lines 1259 may be disposed on other layers of the dielectric layer stack (e.g., third dielectric layer 1270 or fourth dielectric layer 1275).

In some embodiments, as shown for example in the FIG. 12, polysilicon isolation lines 1259 may be situated in the gap A between the central conductor 1287 and the ground planes 1285. The width B of the polysilicon isolation lines 1259 may be smaller than the gap A in the CPW, or wider (width C may be either “positive” or “negative”). Additionally, or alternatively, polysilicon isolation lines may be situated underneath of the CPW ground planes 1285 to limit the PSC layer 1225, to reduce overall coupling with the rest of the circuitry on the same IC.

In some embodiments, transverse polysilicon lines (e.g., polysilicon lines 1157 shown in FIG. 11) with different patterns may be used. Polysilicon resistivity should be substantially high (preferably non-silicide process). Appropriate voltage applied to the polysilicon isolation electrode results in depletion layer 1220 creation on top of the silicon substrate 1215, and insertion loss and non-linear behavior of CPW may be mitigated significantly. In some cases, large coverage area by polysilicon “patches” (not just lines) may be used (e.g., underneath of the central conductor 1287 including gaps between the central conductor 1287 and the ground planes 1285). Isolation of “regular” RF transmission lines may be done in a similar manner. Similar approach could be used to isolate metal inductors and capacitors of an RFIC from the rest of the circuitry on the IC.

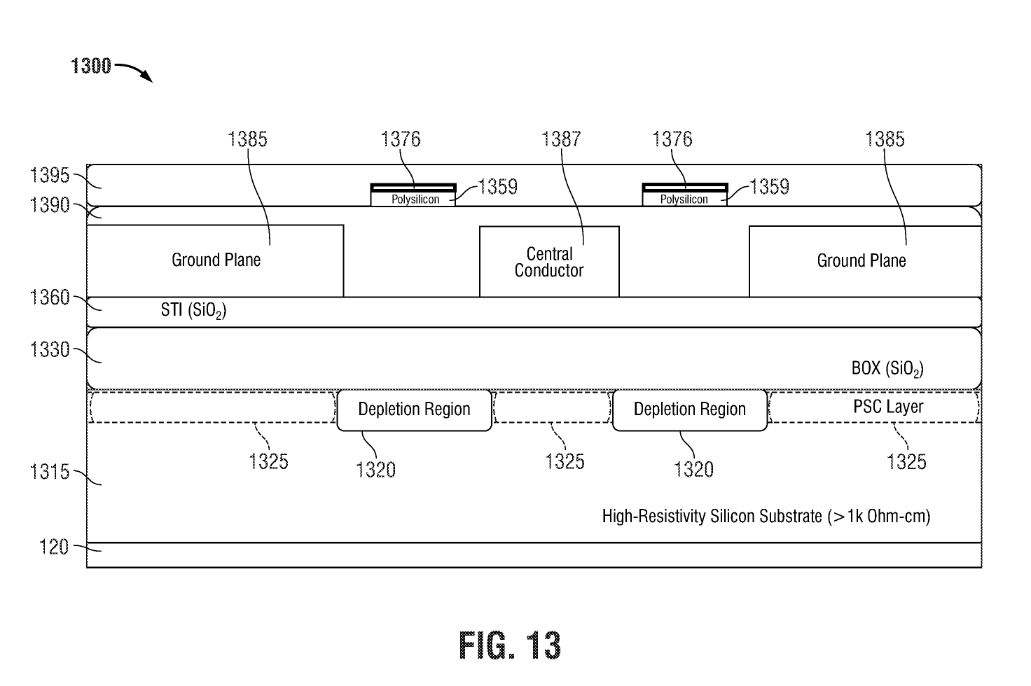

FIG. 13 is a cross-sectional view of a structure 1300 including a SOI substrate, showing CPW separation, in accordance with another embodiment of the present disclosure. The CPW structure is composed of a central conductor line 1387 and ground planes 1385.

The structure 1300 includes a silicon substrate 1315, such as a high-resistivity silicon (HR-Si) substrate 1315, a buried oxide (BOX) layer 1330 overlying the silicon substrate 1315, and a first dielectric layer 1360 situated on the BOX layer 1330. The central conductor line 1387 and ground planes 1385 are formed on the first dielectric layer 1360.

A second dielectric layer 1390 is formed on the first dielectric layer 13680 and covers the CPW. Polysilicon traces 1359 are situated on the second dielectric layer 1390. A silicide layer 1376 is situated on each of the polysilicon traces 1359. In an embodiment, a third dielectric layer 1395 is formed on the second dielectric layer 1390 and covers the polysilicon isolation lines 1359.

Depletion regions 1320 on surface of silicon substrate 1315 can be created by an appropriate bias voltage, which limits the PCS layer 1325. Isolation of “regular” RF lines could be done in similar manner (as well as inductors and capacitors).

The above-described structures including a SOI substrate and methods for fabrication thereof allow use of low-cost SOI high-resistivity substrates for RFIC die manufacturing. The above-described structures and methods for fabrication could be used for low-resistivity SOI substrates as well.

Although embodiments have been described in detail with reference to the accompanying drawings for the purpose of illustration and description, it is to be understood that the disclosed processes and apparatus are not to be construed as limited thereby. It will be apparent to those of ordinary skill in the art that various modifications to the foregoing embodiments may be made without departing from the scope of the disclosure.

What is claimed is:

1. A radio frequency integrated circuit comprising:
a silicon-on-insulator substrate including a buried oxide layer disposed over a silicon substrate and a silicon layer disposed over the buried oxide layer;
at least one transistor disposed on the silicon layer, each transistor including a gate, a drain, a source, and a body; and
a guard-ring on the silicon-on-insulator substrate surrounding the at least one transistor on the silicon layer;
wherein depletion regions on the silicon substrate corresponding to areas surrounding the at least one transistor are defined by the application of a voltage to the guard-ring.

2. The radio frequency integrated circuit of claim 1, wherein the silicon substrate is a high-resistivity silicon substrate.

3. The radio frequency integrated circuit of claim 1, further comprising a gate oxide layer disposed between the guard-ring and the silicon-on-insulator substrate.

4. The radio frequency integrated circuit of claim 1, wherein the guard-ring is a high-resistivity conductive material.

5. The radio frequency integrated circuit of claim 4, wherein the guard-ring is constructed of polysilicon.

6. The radio frequency integrated circuit of claim 1, wherein the body of the at least one transistor is connected to the source thereof.

7. The radio frequency integrated circuit of Claiml, wherein the body of the at least one transistor is independent of the source thereof.

8. The radio frequency integrated circuit of claim 1, wherein the body of the at least one transistor is connected to the drain thereof.

9. The radio frequency integrated circuit of claim 1, wherein the body of the at least one transistor is independent of the drain thereof.

10. The radio frequency integrated circuit of claim 1, wherein the at least one transistor includes first and second n-channel metal oxide semiconductor field effect transistors.

11. The radio frequency integrated circuit of claim 1, wherein the at least one transistor includes a first n-channel metal oxide semiconductor field effect transistor and a second p-channel metal oxide semiconductor field effect transistor.

12. The radio frequency integrated circuit of claim 5, wherein the guard-ring limits a parasitic surface conduction (PSC) layer to one or more portions of the silicon substrate underlying the first and second NMOS transistors.

13. A radio frequency integrated circuit, comprising:
a semiconductor substrate;
a buried oxide layer over the semiconductor substrate;
a first dielectric layer over the buried oxide layer;
at least one radio frequency transmission line over the first dielectric layer; and
at least one polysilicon line disposed on each of the opposite sides of the radio frequency transmission line in a spaced relationship;
wherein depletion regions on the semiconductor substrate corresponding to areas overlapping the at least one polysilicon line are defined by the application of a voltage to the at least one polysilicon line.

14. The radio frequency integrated circuit of claim 13, wherein the at least one polysilicon line limits a parasitic surface conduction layer to one or more portions of the semiconductor substrate underlying the at least one radio frequency transmission line.

15. A radio frequency integrated circuit, comprising:
a semiconductor substrate;
a buried oxide layer over the semiconductor substrate;
a plurality of dielectric layers over the buried oxide layer;
at least one radio frequency transmission line over the plurality of dielectric layers; and
a plurality of isolation traces in a lateral spaced relationship to the at least one radio frequency transmission line, each of the plurality of isolation traces being longitudinally offset on a corresponding one of the plurality of dielectric layers;
wherein depletion regions on the semiconductor substrate corresponding to areas overlapping the plurality of isolation traces are defined by the application of a voltage to the plurality of isolation traces.

16. The radio frequency integrated circuit of claim 15, wherein the plurality of isolation traces are metal layers.

17. The radio frequency integrated circuit of claim 15, wherein the plurality of isolation traces are polysilicon layers.

18. The radio frequency integrated circuit of claim 15, wherein a one of the plurality of isolation traces is placed within a shallow trench isolation (STI) trench defined by a first one of the plurality of dielectric layers.

19. The radio frequency integrated circuit of claim 18, wherein a second one of the plurality of isolation traces is placed on a second one of the plurality of dielectric layers.

20. The radio frequency integrated circuit of claim 18, wherein the isolation traces are disposed on each of the opposite sides of the at least one radio frequency transmission line and are electrically connected together.

21. The radio frequency integrated circuit of claim 20, wherein a distance between each of the plurality of isolation traces is lower than a wavelength of a signal on the radio frequency transmission line.

22. A radio frequency integrated circuit, comprising:
a semiconductor substrate;
a buried oxide layer over the semiconductor substrate;
one or more dielectric layers, a first one of the one or more dielectric layers being disposed over the buried oxide layer;
a coplanar wave guide structure over the first one of the one or more dielectric layers, the coplanar wave guide structure including a ground plane and a central conductor; and
a plurality of first isolation traces in a spaced, parallel relationship to the central conductor, the first isolation traces being disposed within lateral gaps defined by the ground plane and the central conductor;
wherein depletion regions on the semiconductor substrate corresponding to areas overlapping with the plurality of first isolation traces are defined by the application of a voltage to the first isolation traces.

23. The radio frequency integrated circuit of claim 22, wherein the plurality of first isolation traces is disposed on the first one of the one or more dielectric layers.

24. The radio frequency integrated circuit of claim 22, wherein the plurality of first isolation traces is disposed on a second one of the one or more dielectric layers, the second one of the one or more dielectric layers being disposed over the coplanar wave guide structure.

25. The radio frequency integrated circuit of claim 22, wherein the plurality of first isolation traces are polysilicon layers.

26. The radio frequency integrated circuit of claim 22, wherein at least one of the plurality of first isolation traces is disposed under the ground plane.

27. The radio frequency integrated circuit of claim 22, further comprising:
a plurality of second isolation traces in a spaced, parallel relationship to each other and orthogonal to the plurality of first isolation traces;
wherein the depletion regions further corresponding to areas overlapping with the plurality of second isolation traces are defined by the application of a voltage to the second isolation traces.
